(19) United States
(12) Patent Application Publication
(10) Pub. No.: US 2025/0210507 A1
(43) Pub. Date: Jun. 26, 2025

(54) STACKED TRENCH CAPACITORS AND METHODS OF MAKING THEREOF

(71) Applicant: GlobalFoundries U.S. Inc., Malta, NY (US)

(72) Inventors: ANUPAM DUTTA, Bangalore (IN); RUI TZE TOH, Singapore (SG); VVSS SATYASURESH CHOPPALLI, Bangalore (IN); VENKATA NARAYANA RAO VANUKURU, Bangalore (IN); ANANTH SUNDARAM, Bangalore (IN)

(21) Appl. No.: 18/391,742

(22) Filed: Dec. 21, 2023

(51) Int. Cl. H01L 23/522; H01G 4/012; H01G 4/30

(52) U.S. Cl. CPC H01L 23/5223; H01G 4/012; H01G 4/30; H10D 1/692

(57) ABSTRACT

Stacked trench capacitors and methods of making the same are provided. Stacked trench capacitor comprises a first conductive layer and a second conductive layer in a first dielectric layer over a first semiconductor substrate, and a third conductive layer and a fourth conductive layer in a second dielectric layer. The first and second conductive layers are spaced by a first insulator layer, and the third and fourth conductive layers are spaced by a second insulator layer, and the second conductive layer is directly contacting the third conductive layer. A second semiconductor substrate is over the fourth conductive layer.

### FIELD OF THE INVENTION

The present invention relates generally to capacitors in semiconductor devices, and more particularly to stacked trench capacitors and methods of making stacked trench capacitors.

### BACKGROUND

As electronic devices become more compact and yet increasingly multi-functional, the semiconductor chips within these electronic devices are correspondingly required to encompass multiple functionalities while having small form factors. Increasing functionality on the semiconductor chip typically requires increasing the number of electronic components on the chip, hence inevitably increasing the form factor of a 2D semiconductor chip as well. In recent years, the semiconductor industry has progressively adopted 3D stacking of semiconductor chips to provide increased functionality and higher component density while decreasing or maintaining a small form factor.

In 3D stacking processes, semiconductor chips having the same or different functionalities may be stacked and bonded to form multilayer stacked structures. Electronic components may be formed on the separate semiconductor chips (or wafers) before the stacking process or may be formed by additional processes on the stacked structure after the stacking process. Improved methods of forming such electronic components are desired for better efficiency and performance of the electronic devices.

### SUMMARY

According to an embodiment of the invention, a semiconductor device comprises a dielectric layer over a semiconductor substrate, a first conductive layer in the dielectric layer, a capacitor dielectric layer in the dielectric layer, and a second conductive layer in the dielectric layer. The second conductive layer encircles the capacitor dielectric layer and the first conductive layer.

According to another embodiment of the invention, a semiconductor device comprises a first semiconductor substrate having a first active layer, and a first dielectric layer over the first semiconductor substrate. A first conductive layer and a second conductive layer are in the first dielectric layer, and the second conductive layer is above the first conductive layer. A first insulator layer is over the first conductive layer, where the first insulator layer spaces the first conductive layer from the second conductive layer. A third conductive layer and a fourth conductive layer are in a second dielectric layer, where the third conductive layer is directly contacting the second conductive layer. The fourth conductive layer is above the third conductive layer, where the third conductive layer has sidewalls adjoining a top surface. A second insulator layer is over and conformal to the sidewalls and the top surface of the third conductive layer, where the second insulator layer spaces the third conductive layer from the fourth conductive layer. A second semiconductor substrate is over the fourth conductive layer, where the second semiconductor substrate has a second active layer.

According to yet another embodiment of the invention, a method of fabricating a semiconductor device is provided. The method includes forming a first trench capacitor, including forming a first conductive layer, a first insulator layer and a second conductive layer in a first dielectric layer. The second conductive layer is above the first conductive layer and the first insulator layer spaces the first conductive layer from the second conductive layer. The method further includes forming a second trench capacitor, which includes forming a third conductive layer, a second insulator layer and a fourth conductive layer in a second dielectric layer. The third conductive layer is above the fourth conductive layer and the second insulator layer spaces the third conductive layer from the fourth conductive layer. The method further includes inverting and arranging the second trench capacitor over the first trench capacitor such that the first conductive layer is contacting the fourth conductive layer and the second conductive layer is contacting the third conductive layer, and bonding the first conductive layer to the fourth conductive layer and the second conductive layer to the third conductive layer.

### BRIEF DESCRIPTION OF THE DRAWINGS

The accompanying drawings illustrate examples of various non-limiting embodiments of the invention and constitute a part of the specification. The drawings, along with the above general description of the invention, and the following detailed description of the various embodiments, serve to explain the examples of the non-limiting embodiments of the invention. In the drawings, like reference numerals generally refer to like features in the various views.

FIG. 1A shows a simplified cross-sectional view of a stacked trench capacitor 100, according to an exemplary embodiment of the disclosure.

FIG. 1B shows a simplified cross-sectional view of a stacked trench capacitor 200, according to another exemplary embodiment of the disclosure.

FIG. 2 shows a simplified cross-sectional view of a stacked trench capacitor 300, according to an exemplary embodiment of the disclosure.

FIGS. 3A-3D show simplified cross-sectional views representing exemplary process steps for fabricating the stacked trench capacitor 100, according to exemplary embodiments of the invention.

FIGS. 4A-4E show simplified cross-sectional views representing exemplary process steps for fabricating the stacked trench capacitor 300, according to exemplary embodiments of the invention.

For simplicity and clarity of illustration, the drawings illustrate the general manner of construction, and certain descriptions and details of well-known features and techniques may be omitted to avoid unnecessarily obscuring the discussion of the described embodiments of the device. Additionally, elements in the drawings are not necessarily drawn to scale and the dimensions of some of the elements in the drawings may be exaggerated relative to other elements to help improve understanding of the embodiments of the device.

### DETAILED DESCRIPTION

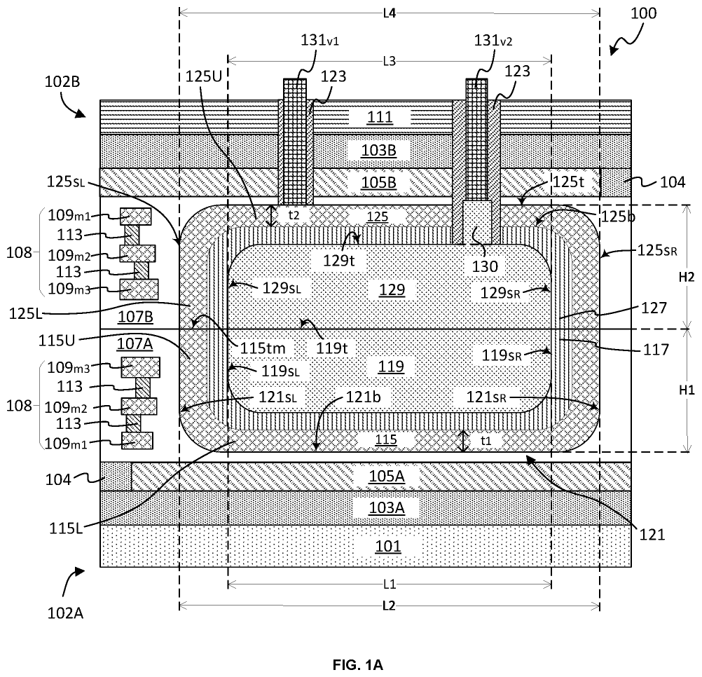

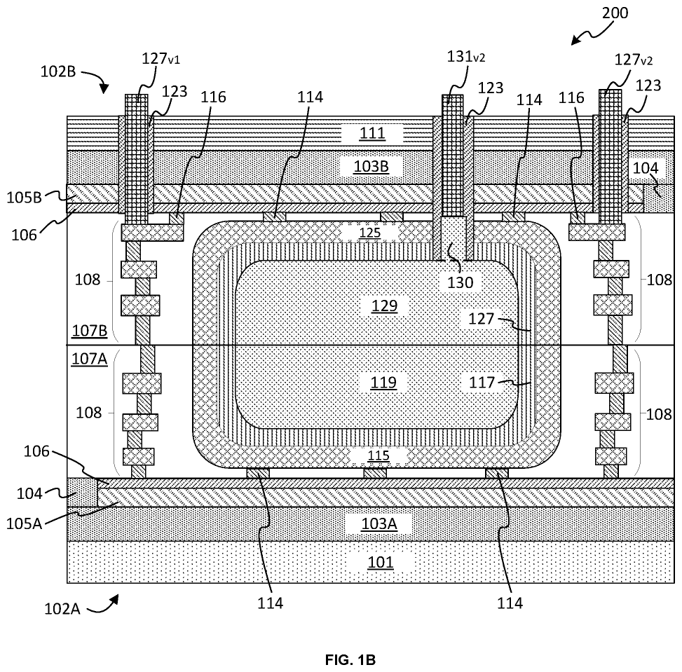

According to an exemplary embodiment of the disclosure, FIG. 1A shows a stacked trench capacitor 100 which includes a conductive layer 139, a capacitor dielectric layer 137, and another conductive layer 135 in a dielectric layer 107. The capacitor dielectric layer 137 may be around the conductive layer 139, and another conductive layer 135 may be around the capacitor dielectric layer 137 and the conductive layer 139. Dielectric layer 107 may comprise dielectric layer 107A and dielectric layer 107B. In some embodiments, the capacitor dielectric layer 137 may encircle the conductive layer 139, and the conductive layer 135 may encircle the capacitor dielectric layer 137 and the conductive layer 139. The conductive layer 139 may comprise a conductive layer 129 in a first trench capacitor 102A over another conductive layer 119 in a second trench capacitor 102B. The capacitor dielectric layer 137 may comprise an insulator layer 127 in the first trench capacitor 102A, which is above and connected to another insulator layer 117 in the second trench capacitor 102B. The conductive layer 135 may comprise a conductive layer 125 in the first trench capacitor 102A and another conductive layer 115 in the second trench capacitor 102B. The second trench capacitor 102B may be stacked on top of the first trench capacitor 102A. The first trench capacitor 102A may include an active layer 105A over a substrate 101 and a dielectric layer 107A over the active layer 105A. A shallow trench isolation (STI) region 104 may be adjacent to the active layer 105A and provide electrical isolation of the active region from the other non-active regions. In some embodiments, the dielectric layer 107A may be in direct contact with the active layer 105A. The second trench capacitor 102B may include another active layer 105B over a dielectric layer 107B. A shallow trench isolation (STI) region 104 may also be adjacent to the active layer 105B. The dielectric layer 107B is stacked over and connected to the dielectric layer 107A of the first trench capacitor 102A. In some embodiments, the dielectric layer 107B may be in direct contact with the active layer 105B. Dielectric layers 107A and 107B may each be an interlayer dielectric layer. In exemplary embodiments, dielectric layers 107A and 107B may each have a low dielectric constant. Dielectric layers 107A and 107B may further include one or more interconnect structure 108 adjacent to and spaced from the first trench capacitor 102A and/or the second trench capacitor 102B. Interconnect structure 108 may be located in the interconnects layer within the semiconductor structure, and may include vias 113 connecting metal lines 109mx, where x corresponds to the metal level in the interconnect layer, for example, 109m1 may correspond to the first metal level (M1) within the interconnect layer of the semiconductor device. In some embodiments, interconnect structure 108 is not electrically connected to any electrical inputs or outputs. For example, interconnect structure 108 may be electrically floating.

Now referring back to FIG. 1A, the first trench capacitor 102A may include an insulating layer 103A between the active layer 105A and the substrate 101. The active layer 105A may comprise a semiconductor material, for example, silicon. The substrate 101 may include but is not limited to silicon, germanium, silicon germanium (SiGe), silicon carbide, gallium arsenide, or any other suitable integrated circuit (IC) semiconductor substrates. In some embodiments, substrate 101 may be an undoped substrate. In some other embodiments, substrate 101 may be doped with a dopant, such as p-type or n-type dopants. The insulating layer 103A may include but is not limited to a buried oxide (BOX) layer, for example, silicon dioxide. In some embodiments, a silicon-on-insulator (SOI) substrate may be used in place of the substrate 101, insulating layer 103A and active layer 105A.

Still referring to FIG. 1A, dielectric layer 107A of the first trench capacitor 102A may include a trench 121 having a conductive layer 115, an insulator layer 117 and another conductive layer 119. The trench 121 may have trench sidewalls, 121_{SL} and 121_{SR}, adjoining a bottom trench surface 121b. For example, the bottom trench surface 121b may have one end adjoining the trench sidewall 121_{SL} and an opposing end adjoining the other trench sidewall 121_{SR}. Trench sidewall 121L and trench sidewall 121_{SR} may be spaced apart and facing each other. The conductive layer 115 may line the surfaces of the trench 121. For example, the conductive layer 115 may be conformal to the trench sidewalls 121_{SL} and 121_{SR}, and to the bottom trench surface 121b. In an embodiment, the width L2 of the conductive layer 115 may be taken from the trench sidewall 121_{SL} to the other trench sidewall 121_{SR}. In some embodiments, the width L2 of the conductive layer 115 may be representative of the width of the conductive layer 135. The width L2 of the conductive layer 115 may be wider than the width L1 of the conductive layer 119. In some embodiments, the width L1 of the conductive layer 119 may be representative of the width of the conductive layer 139. For example, the width L2 of the conductive layer 135 may be wider than the width L1 of the conductive layer 139. The conductive layer 115 may comprise a lower portion 115L and an upper portion 115U that adjoins the lower portion 115L to make up the continuous layer. The lower portion 115L may be in direct contact with the bottom trench surface 121b and the lower portions of the trench sidewalls 121_{SL} and 121_{SR}, while the upper portion 115U may be in direct contact with at least the upper portions of the trench sidewalls 121_{SL} and 121_{SR}. In some embodiments, the lower portion 115L may be at least partially arranged in the first metal (M1) level within the interconnect of the first trench capacitor 102A. The lower portion 115L may include a middle section that is substantially horizontal and having a thickness t1 that may be substantially similar to the thickness of the first metal line 109m1 of the first trench capacitor 102A. The upper portion 115U may be substantially vertical, or slanted at an angle, depending on the design requirements and the process used for forming the trench 121. The conductive layer 115 may further include a topmost surface 115tm at one end of the upper portion 115U, which is distal from the lower portion 115L. The other conductive layer 119 may be above the conductive layer 115 such that conductive layer 119 laterally overlaps with at least the lower portion 115L of the conductive layer 115. Conductive layer 119 may be laterally adjacent to the upper portion 115U and may have a top surface 119t that may be coplanar with a top surface of the conductive layer 115, for example, the topmost surface 115tm. The conductive layer 119 may have a height H1 taken from the topmost surface 115tm to the bottom surface of the lower portion 115L. Conductive layer 119 may have sidewalls 119_{SL} and 119_{SR} that are facing the trench sidewalls, 121_{SL} and 121_{SR} respectively, and a bottom surface that faces the bottom trench surface 121b. Conductive layer 119 may have a width L1 taken from sidewall 119_{SL} to sidewall 119_{SR}. Conductive layer 119 may be spaced from conductive layer 115 by the insulator layer 117. The insulator layer 117 may be over the conductive layer 115, such that the insulator layer 117 is in direct contact with the upper portion 115U and lower portion 115L of the conductive layer 115. The insulator layer 117 may comprise a single layer of insulating material or may comprise multiple layers of insulating materials. In some embodiments, insulator layer 117 may have a high dielectric constant (high-K). Suitable insulating materials may include a nitride material, for example, silicon nitride (SiN), or an oxide material, for example, silicon dioxide (SiO₂) or aluminum oxide (AlO).

Next referring to the second trench capacitor 102B, which includes the active layer 105B over the dielectric layer 107B. An insulating layer 103B may be over the active layer 105B and an oxide layer 111 may be over the insulating layer 103B. The active layer 105B may be similar to active layer 105A and comprise the same materials. The insulating layer 103B may also be similar to insulating layer 103A and comprise the same materials. The second trench capacitor 102B may further include a conductive layer 125 over another conductive layer 129, where the conductive layer 125 is spaced apart from the conductive layer 129 by an insulator layer 127.

The conductive layer 129 may have a top surface 129t adjoining the sidewalls 129_{SL} and 129_{SR}. The conductive layer 129 may have a width L3 taken from sidewall 129_{SL} to the opposite sidewall 129_{SR}. In an embodiment, a middle section of the top surface 129t may be substantially horizontal. The conductive layer 129 of the second trench capacitor 102B may be over and laterally overlap with the conductive layer 119 of the first trench capacitor 102A. In some embodiments, the conductive layer 129 may be connected with the conductive layer 119. For example, the conductive layers 119 and 129 may be in direct contact and electrically connected. In some embodiments, the width L3 of conductive layer 129 may be substantially the same as the width L1 of the conductive layer 119.

The other conductive layer 125 may be arranged above and laterally overlaps with the conductive layer 129. In some embodiments, the conductive layer 129 may be completely underneath the conductive layer 125. The conductive layer 125 may include an internal sidewall and an external sidewall that is opposite to the internal sidewall. The internal sidewall faces the conductive layer 129 and may be in contact with the insulator layer 127. The external sidewall, for example, 125_{SL} or 125_{SR}, may be in contact with the dielectric layer 107B.

The conductive layer 125 may comprise a lower portion 125L connected to an upper portion 125U. The lower portion 125L may include a left lower portion connected to one end of the upper portion 125U and a right lower portion connected to another end of the upper portion 125U. For example, the upper portion 125U may be connected to and between the lower portions. The lower portion 125L may be substantially vertical, or slanted at an angle to the vertical, depending on the design requirements and the process used for forming the conductive layer 125. The lower portion 125L may include at least the lower portions of the internal and external sidewalls of the conductive layer 125 that are adjoined by a bottom surface that is in contact with the conductive layer 115. For example, the lower portion 125L may be in direct contact with the topmost surface 115tm such that conductive layers 115 and 125 are electrically connected. The lower portions of the conductive layer 125 may be laterally adjacent to the conductive layer 129. The upper portion 125U of the conductive layer 125 may include a middle section that may be substantially horizontal. In some embodiments, the upper portion 125U may be at least partially arranged in the first metal (M1) level within the interconnect of the second trench capacitor 102B. The upper portion 125U may further include a top surface 125t that is in direct contact with the dielectric layer 107B and a bottom surface 125b that is in direct contact with the insulator layer 127. The upper portion 125U may have a thickness t2 measured from the top surface 125t to the bottom surface 125b. In some embodiments, the thickness t2 may be substantially similar to the thickness of the first metal line 109m1 of the second trench capacitor 102B. The thickness t2 of the upper portion 125U may be substantially uniform for at least a middle region of the upper portion 125U. In some embodiments, the top surface 125t may be a topmost surface of the conductive layer 125. In some embodiments, the upper portion 125U may include upper portions of the external sidewalls 125_{SL} and 125_{SR}.

The conductive layer 125 may have a width L4 measured from the external sidewall 125_{SL} to the opposite external sidewall 125_{SR}. In some embodiments, the width of the upper portion 125U of the conductive layer 125 may be the same as the width L4 of the conductive layer 125. In an embodiment, the width L4 of the conductive layer 125 may be wider than the width of the conductive layer 129. For example, the conductive layer 125 may have a width LA that is wider than the width L3 of the conductive layer 129. In some embodiments, the width L4 of the conductive layer 125 may be representative of the width of the conductive layer 135, while the width L3 of the conductive layer 129 may be representative of the width of the conductive layer 139. For example, the conductive layer 135 may have a width L4 that is wider than the width L3 of the conductive layer 139. In some embodiments, the width LA of the conductive layer 125 may be substantially the same as the width L2 of the conductive layer 115. The conductive layer 125 may have a height H2 taken from the top surface 125t to the bottom surface of the lower portion 125L that is in contact with the conductive layer 115. In some embodiments, the height H2 of the conductive layer 125 may be substantially equal to the height H1 of the conductive layer 115.

The conductive layers 125 and 129 are spaced apart by the insulator layer 127. The insulator layer 127 may comprise single or multiple layers and may include similar materials as insulator layer 117 as listed above. In an embodiment, insulator layer 127 may be connected to insulator layer 117. For example, insulator layer 127 may be in direct contact with insulator layer 117.

FIG. 1A also shows the second trench capacitor 102B on top of the first trench capacitor 102A. The dielectric layer 107B in the second trench capacitor 102B may be adjacent to the conductive layer 125. In some embodiments, the dielectric layer 107B may encapsulate the conductive layer 125. For example, the dielectric layer 107B may be in direct contact with an external surface of the conductive layer 125 that includes the top surface 125t of the upper portion 125U, and the external sidewalls 125_{SL} and 125_{SR} of the lower portion 125L. In some embodiments, the dielectric layer 107B may have an upper surface that may be adjacent to and be in direct contact with the active layer 105B. In other embodiments, the dielectric layer 107B may have an upper surface that may be adjacent to and be in direct contact with a silicided region 106 as shown in FIG. 1B.

The second trench capacitor 102B may further include a conductive plug 130 on the conductive layer 129. The conductive plug 130 may be electrically connected to conductive layer 129. In some embodiments, the conductive plug 130 may comprise a different material from the conductive layer 129. In other embodiments, the conductive plug 130 may comprise the same material as the conductive layer 129. The conductive plug 130 may extend from the top surface 129t of the conductive layer 129 through the insulator layer 127. The conductive plug 130 may be connected to a via contact 131v2 that extends through the dielectric layer 107B, the active layer 105B, the insulating layer 103B and the oxide layer 111. The conductive plug 130 and the via contact 131v2 may be electrically insulated from the active layer 105B and the conductive layer 125 by an insulating material 123 which covers the sidewalls of the conductive plug 130 and the sidewalls of the via contact 131v2. In some embodiments, the insulating material 123 is in direct contact with the sidewalls of the conductive plug 130 and the sidewalls of the via contact 131v2. The second trench capacitor 102B may also include another via contact 131v1 on conductive layer 125. The via contact 131v1 may be electrically connected to conductive layer 125 and extend from the top surface of conductive layer 125 through the dielectric layer 107B, the active layer 105B, the insulating layer 103B and the oxide layer 111. Similarly, the via contact 131v1 may be electrically insulated from the active layer 105B by an insulating material 123 which covers the sidewalls of the via contact 131v1. Via contacts 131v1 and 131v2 may comprise a conductive material, for example, a metallic material, such as copper (Cu). In some embodiments, via contacts 131v1 and 131v2 may comprise the same material as the conductive plug 130. In other embodiments, via contacts 131v1 and 131v2 may comprise a different material from the conductive plug 130.

The conductive layers 115, 119, 125 and 129 may comprise a metallic material such as titanium (Ti), copper (Cu), cobalt (Co), aluminum (Al), gold (Au), silver (Ag), their alloys or compounds thereof. In some embodiments, the conductive layers 115, 119, 125 and 129 may include a liner under the metallic material. For example, the conductive layer may comprise a titanium nitride liner (TiN) and aluminum (Al) over the TiN liner. In other embodiments, the conductive layers 115, 119, 125 and 129 may comprise doped semiconductor materials, for example, highly doped poly silicon material.

In accordance with another embodiment of the disclosure, FIG. 1B shows stacked trench capacitor 200 having silicided regions 106 in the first and second trench capacitors 102A and 102B. Like numerals in FIG. 1B may denote like features in FIG. 1A. In exemplary embodiments, the first trench capacitor 102A may include a silicided region 106 adjacent to active layer 105A. The second trench capacitor 102B may include a silicided region 106 adjacent to active layer 105B. In some embodiments, the conductive layer 115 of the first trench capacitor 102A may be connected to the silicided region 106 above the active layer 105A by one or more vias 114. Similarly, the conductive layer 125 of the second trench capacitor 102B may be connected to the silicided region 106 below the active layer 105B by one or more vias 114. The silicided region 106 adjacent to the active layer 105B may in turn be connected to one of the metal lines in the interconnect structure 108 by one or more vias 116. In such embodiments, the via contact 131v1 (as shown in FIG. 1A) connecting to the conductive layer 125 may be absent. In other embodiments, the conductive layer 125 may be connected to via contact 131v1, and conductive layers 115 and 125 may not be connected to the silicided regions 106. Still referring to FIG. 1B, interconnect structure 108 may be connected to a silicided region 106 adjacent to active layer 105A and/or active layer 105B. For example, the silicided regions 106 in the first trench capacitor 102A may be connected to the interconnect structures 108 in the dielectric layer 107A, and the silicided regions 106 in the second trench capacitor 102B may be connected to the interconnect structures 108 in the dielectric layer 107B. The interconnect structures 108 in dielectric layers 107A and 107B may be connected to each other and also connected to vias 127v1 and 127v2 which may in turn be connected to ground. The above-described embodiments may help to reduce parasitic resistance in the stacked trench capacitor 200.

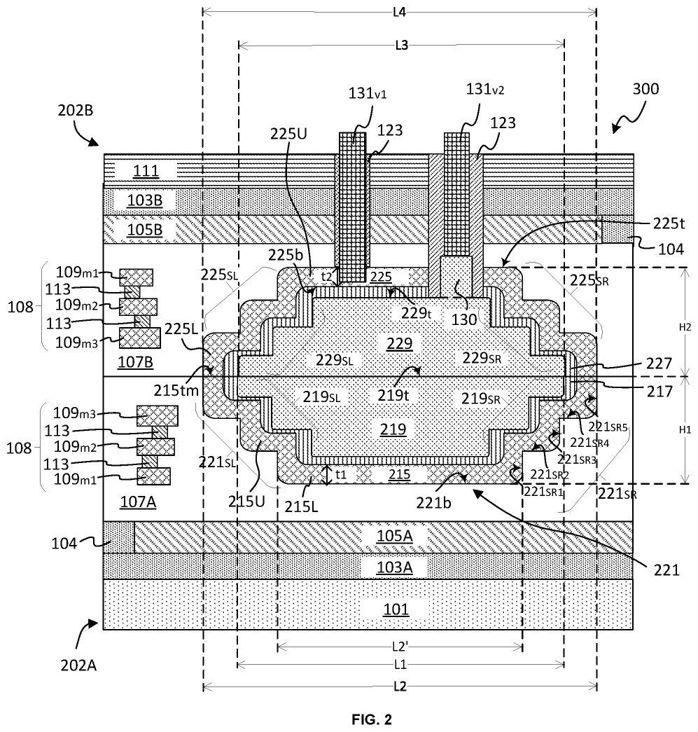

FIG. 2 shows a stacked trench capacitor 300, according to another embodiment of the disclosure. Like numerals in FIG. 2 may denote like features in FIG. 1A. The stacked trench capacitor 300 may include a conductive layer 239, a capacitor dielectric layer 237 and another conductive layer 235 in the dielectric layer 107. The capacitor dielectric layer 237 may be around the conductive layer 239, and another conductive layer 235 may be around the capacitor dielectric layer 237 and the conductive layer 239. In some embodiments, the capacitor dielectric layer 237 may encircle the conductive layer 239, while the conductive layer 235 may encircle the capacitor dielectric layer 237 and the conductive layer 239. The conductive layer 239 may comprise a conductive layer 229 in a first trench capacitor 102A and another conductive layer 219 in a second trench capacitor 102B. The capacitor dielectric layer 237 may comprise an insulator layer 227 in the first trench capacitor 102A, which is above and connected to another insulator layer 217 in the second trench capacitor 102B. The conductive layer 235 may comprise a conductive layer 225 in the first trench capacitor 102A and another conductive layer 215 in the second trench capacitor 102B. The second trench capacitor 202B may be stacked on top of the first trench capacitor 202A. The trench capacitors 202A and 202B include components similar to trench capacitors 102A and 102B as aforementioned, for example, substrate 101, active layers 105A and 105B, dielectric layer 107 comprising dielectric layers 107A and 107B, insulating layers 103A and 103B, via contacts 131v1 and 131v2, insulating material 123 and interconnect structures 108, and hence will not be further described here. The first trench capacitor 202A may include a trench 221 having trench sidewalls 221_{SL} and 221_{SR}, adjoining a bottom trench surface 221b. For example, the bottom trench surface 221b may have one end adjoining the trench sidewall 221_{SL} and an opposing end adjoining the other trench sidewall 221_{SR}. Trench sidewall 221_{SL} and trench sidewall 221_{SR} may be spaced apart and facing each other. Each trench sidewall may each have a stepped profile comprising at least one step. For example, trench sidewall 221_{SR} may include sub-surfaces 221_{SR1}, 221_{SR2}, 221_{SR3}, 221_{SR4} and 221_{SR5} that are adjacent to each other and adjoining each other at an angle to form a series of steps. A step may be defined as two sub-surfaces adjoining each other to form an angle, which may be an acute angle, a right angle or an obtuse angle, depending on the process used to form the trench 221. As a further illustration, sub-surface 221_{SR1} may adjoin the adjacent sub-surface 221_{SR2} at an angle to form a first step, while sub-surface 221_{SR3} may adjoin the adjacent sub-surface 221_{SR4} at an angle to form a second step. The first step adjoins the second step and the second step adjoins the sub-surface 221_{SR5} to collectively form the trench sidewall 221_{SR}.

The conductive layer 215 may line the surfaces of the trench 221. For example, the conductive layer 215 may be conformal to the trench sidewalls 221_{SL} and 221_{SR}, and to the bottom trench surface 221b. The conductive layer 215 may comprise an upper portion 215U which is in direct contact with at least the upper portions of the trench sidewalls 221_{SL} and 221_{SR}, and a lower portion 215L which is in direct contact with the bottom trench surface 221b and the lower portions of the trench sidewalls 221_{SL} and 221_{SR}. The upper portion 215U may be conformal to the upper portions of the trench sidewalls 221_{SL} and 221_{SR}. For example, the upper portion 215U may have sidewalls having a stepped profile corresponding to that of the trench sidewalls of trench 221. The conductive layer 215 may further include a topmost surface 215tm at one end of the upper portion 215U, which is distal from the lower portion 215L. The upper portion 215U may have an upper width L2 measured from a first point on an upper portion of the trench sidewall 221_{SL} to a second point on an upper portion of the trench sidewall 221_{SR}. For example, the upper width L2 may be measured between sub-surfaces 221_{SR5} and 221_{SL5} of the trench 221. In some embodiments, the upper width L2 of the upper portion of the conductive layer 215 may be representative of the width of the conductive layer 235. In some embodiments, the lower portion 215L may have at least a middle section that is substantially horizontal and may have a substantially uniform thickness t1. The lower portion 215L may also have a lower width L2′ measured from a first point on a lower portion of the trench sidewall 221_{SL} to a second point on a lower portion of the trench sidewall 225_{SR}. For example, the lower width L2′ may be measured between sub-surfaces 221_{SR1} and 221_{SL1} of the trench 221. In some embodiments, the lower width L2′ may be shorter than the upper width L2 of the conductive layer 215. The conductive layer 215 may have a height H1 taken from the bottom surface of the lower portion 215L to the topmost surface 215tm.

The other conductive layer 219 may be above the conductive layer 215 such that conductive layer 219 laterally overlaps with at least the lower portion 215L of the conductive layer 215. In some embodiments, the conductive layer 219 may further extend beyond the lower portion 215L to laterally overlap with a part of the upper portion 215U of the conductive layer 215. Conductive layer 219 may be laterally adjacent to the upper portion 215U and may have a top surface 219t that may be coplanar with a top surface of the conductive layer 215, for example, the topmost surface 215tm. Conductive layer 219 may further include sidewalls 219_{SL} and 219_{SR} that are facing the trench sidewalls, 221_{SL} and 221_{SR} respectively, and a bottom surface that faces the bottom trench surface 221b. In some embodiments, sidewalls 219_{SL} and 219_{SR} may each have a stepped profile corresponding to the stepped profile of trench sidewalls 221_{SL} and 221_{SR} respectively. The conductive layer 219 may have a width taken from the sidewall 219_{SL} to the other sidewall 219_{SR}. For example, the conductive layer 219 may have an upper width L1 taken from a first point on the sidewall 219_{SL} that is furthest from the opposite sidewall 219_{SR} to a second point on the sidewall 219_{SR} that is furthest from the opposite sidewall 219_{SL}. In some embodiments, the width L1 of the conductive layer 219 may be representative of the width of the conductive layer 239. For example, the width L2 of the conductive layer 235 may be wider than the width L1 of the conductive layer 239.

The conductive layer 219 may be spaced from the conductive layer 215 by the insulator layer 217. The insulator layer 217 may be over the conductive layer 215, such that the insulator layer 217 is in direct contact with the upper portion 215U and lower portion 215L of the conductive layer 215. The insulator layer 217 may comprise a single layer of insulating material or may comprise multiple layers of insulating materials. Suitable insulating materials may include a nitride material, for example, silicon nitride (SiN), or an oxide material, for example, silicon dioxide (SiO₂) or aluminum oxide (AlO).

Next referring to the second trench capacitor 202B that is stacked over the first trench capacitor 202A. The second trench capacitor 202B may include a conductive layer 225 over another conductive layer 229. The conductive layer 225 may be spaced apart from the conductive layer 229 by an insulator layer 227. The insulator layer 227 may comprise single or multiple layers and may include similar materials as insulator layer 217 as listed above. In an embodiment, insulator layer 227 may be connected to insulator layer 217. For example, insulator layer 227 may be in direct contact with insulator layer 217.

The conductive layer 229 may have a top surface 229t adjoining the sidewalls 229_{SL} and 229_{SR}. The conductive layer 229 may have a width L3 taken from a first point on the sidewall 229_{SL} that is furthest from the opposite sidewall 229_{SR} to a second point on the sidewall 229_{SR} that is furthest from the opposite sidewall 229_{SL}. In an embodiment, a middle portion of the top surface 229t may be substantially horizontal. The conductive layer 229 of the second trench capacitor 202B may be over and laterally overlap with the conductive layer 219 of the first trench capacitor 202A. In some embodiments, the conductive layer 229 may be connected with the conductive layer 219 of the first trench capacitor 202A. For example, the conductive layers 219 and 229 may be in direct contact and electrically connected.

The other conductive layer 225 may be arranged above and laterally overlaps with the conductive layer 229. In some embodiments, the conductive layer 229 may be completely underneath the conductive layer 225. The conductive layer 225 may have an internal sidewall and an external sidewall that is opposite to the internal sidewall. The internal sidewall faces the conductive layer 229 and may be in contact with the insulator layer 227. The external sidewall, for example, 225_{SL} or 225_{SR}, may be in contact with the dielectric layer 107B. Each of the external sidewalls may have a stepped profile. The conductive layer 225 comprises an upper portion 225U connected to a lower portion 225L. The upper portion 225U may be substantially horizontal and may include a top surface 225t that is in direct contact with the dielectric layer 107B, a bottom surface 225b that is in direct contact with the insulator layer 227, and a thickness t2 measured from the top surface 225t to the bottom surface 225b. The thickness t2 of the upper portion 225U may be substantially uniform for at least a middle region of the upper portion 225U. In some embodiments, the top surface 225t may be a topmost surface of the conductive layer 225. The lower portion 225L may further include a bottom surface that is in contact with the conductive layer 215, for example, the lower portion 225L may be in direct contact with the topmost surface 215tm such that conductive layers 215 and 225 are electrically connected. The conductive layer 225 may have a width LA measured from a first point on the external sidewall 225_{SL} that is furthest from the opposite external sidewall 225_{SR} to a second point on the external sidewall 225_{SR} that is furthest from the opposite external sidewall 225_{SL}. In an embodiment, the width of the conductive layer 225 may be wider than the width of the conductive layer 229. For example, the conductive layer 225 may have a width LA that is wider than the width L3 of the conductive layer 229. In some embodiments, the width L2 of the conductive layer 215 of the first trench capacitor 202A may be substantially similar to the width L4 of the conductive layer 225 of the second trench capacitor 202B.

The dielectric layer 107B in the second trench capacitor 202B may be adjacent to and encapsulate the conductive layer 225. For example, the dielectric layer 107B may be in direct contact with an external surface of the conductive layer 225 that includes the top surface 225t of the upper portion 225U, and the external sidewalls 225_{SL} and 225_{SR} of the lower portion 225L. The dielectric layer 107B may be stacked over and connected to the dielectric layer 107A of the first trench capacitor 202A. In some embodiments, the dielectric layer 107B may have an upper surface that may be adjacent to and be in direct contact with the active layer 105B. In other embodiments (not shown), the dielectric layer 107B may have an upper surface that may be adjacent to and be in direct contact with a silicided region like the silicided region 106 shown in FIG. 1B.

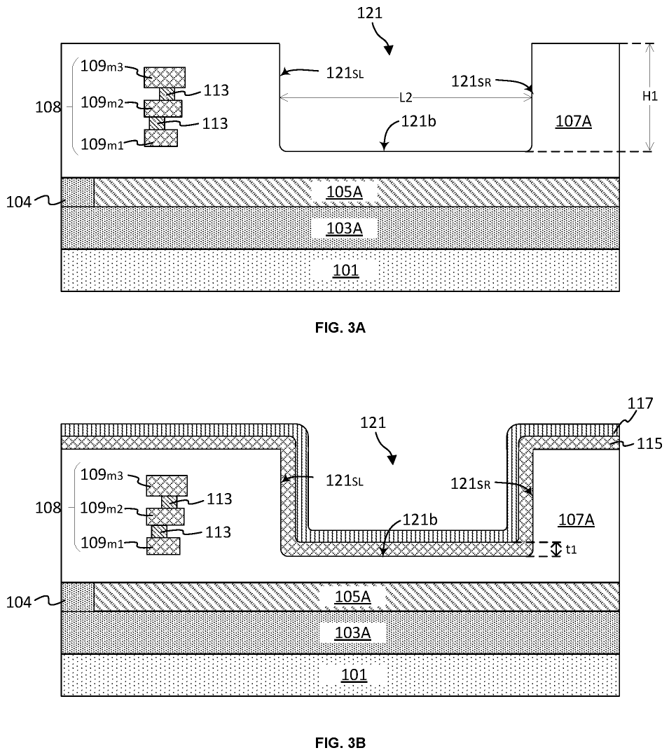

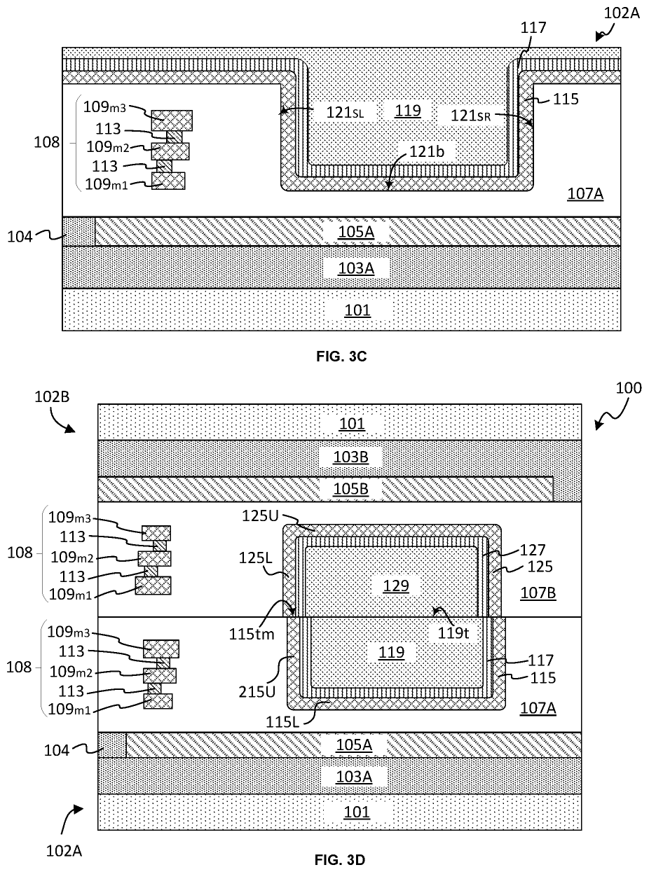

FIGS. 3A-3D illustrate an exemplary process flow for fabricating the stacked trench capacitor 100 according to some embodiments of the invention. First referring to FIG. 3A, an active layer 105A over a substrate 101 may be provided, with a shallow trench isolation (STI) region 104 adjacent to the active layer 105A to provide electrical isolation of the active region from the other non-active regions. An insulating layer 103A may be provided between the active layer 105A and the substrate 101. A dielectric layer 107A may be formed over the active layer 105A by depositing a layer of a suitable dielectric material having a low dielectric constant value (low-K), for example, silicon dioxide, high-density plasma chemical vapor deposition (HDP-CVD) oxide, undoped silicate glass (USG), tetraethyl orthosilicate (TEOS), or any other suitable dielectric material, followed by a suitable material removal process, for example, chemical mechanical planarization or etching process. To form the trench 121, a suitable material removal process including the use of a patterned mask may be applied. As an example, a layer of photoresist may be deposited over the dielectric layer 107A and patterned to form a suitable patterned mask. An anisotropic wet etch or dry etch process may be used to remove the portion of the dielectric layer 107A uncovered by the patterned mask, forming the trench 121 having a bottom trench surface 121b and trench sidewalls 121_{SL} and 121_{SR}. The trench 121 may have a depth of H1 and a width of L2 which is measured from trench sidewall 121 SL to the opposite trench sidewall 121_{SR}. In some embodiments, the depth H1 of the trench may be about 10 microns (μm) and the width L1 may be less than 2 microns (μm). The photoresist pattern may subsequently be removed. The depth H1 of the trench 121 may extend to reach the depth of the first metal (M1) level of the interconnect layer in the semiconductor device, for example, at the depth of the first metal line 109m1 at the first metal (M1) level within the interconnect layer. In some embodiments, the depth H1 of the trench 121 may be at least the depth of the first metal (M1) level. For example, the bottom trench surface is at or above the first metal (M1) level in the semiconductor device. In other embodiments, the bottom trench surface may be at a metal level above the first metal (M1) level, for example, at the second metal (M2) level. In some embodiments, the interconnect structure 108 is formed at an earlier process step before the trench 121 is formed. In other embodiments, the trench 121 may be formed during the process of forming the interconnect structure 108.

Next referring to FIG. 3B in which a conductive layer 115 has been conformally deposited over the dielectric layer 107A and within the trench 121, the conductive layer 115 lining the trench sidewalls 121_{SL} and 121_{SR}, and the bottom trench surface 121b in a continuous layer. The term “conformal” may refer to when a material layer conforms to or follows the contours of the surface that the material layer is in direct contact with, while maintaining a relatively uniform thickness over the surface. The conductive layer 115 may be deposited to have a thickness t1 at the lower portion 115L, where the thickness t may be substantially similar to the thickness of the first metal line 109m1. In other embodiments, the thickness t1 may be thicker or thinner than the thickness of the first metal line 109m1. A suitable deposition method may be plasma-enhanced chemical vapor deposition (PECVD) as an example. The process of forming the conductive layer 115 may include first depositing a liner layer over the trench sidewalls 121_{SL} and 121_{SR}, and the bottom trench surface 121b, followed by the deposition of a metallic layer over the liner layer. The liner layer may be a diffusion barrier layer which may prevent the metallic layer from diffusing into the dielectric layer 107A. In some embodiments, the thickness of the liner layer may be in the range of 10 to 20 nanometers (nm), while the thickness of the conductive layer 115 may be in the range of 100 to 500 nanometers (nm). Next, an insulator layer 117 is deposited over the conductive layer 115 with a suitable process, such as low-pressure chemical vapor deposition (LPCVD), plasma-enhanced chemical vapor deposition (PECVD) as examples. In some embodiments, the thickness of the insulator layer 117 may be in the range of 50 to 500 nanometers (nm).

Next referring to FIG. 3C, another conductive layer 119 has been deposited over the insulator layer 117 and within the trench 121. Conductive layer 119 may fill up the remaining space within the trench 121 and over the topmost surface of the dielectric layer 107A. A suitable deposition method may be plasma-enhanced chemical vapor deposition (PECVD) as an example. Subsequently, to obtain a planar or substantially planar top surface where the top surfaces of dielectric layer 107A, conductive layer 115, and conductive layer 119 are coplanar or substantially coplanar, a suitable material removal process may be performed prior to the stacking of the trench capacitors as shown in FIG. 3D. A suitable material removal process may be, for example, chemical mechanical planarization or an etching process to remove the excess material from the top surface of the device. After the material removal process, the top surface 119t of the conductive layer 119 is coplanar with the topmost surface 115tm of the conductive layer 115 and the top surface of the dielectric layer 107A. The first trench capacitor 102A is now completed, having a coplanar top surface suitable for the subsequent stacking process. In some embodiments, the first trench capacitor 102A may be arranged in an array within a wafer, comprising similar trench capacitors. In other embodiments, the first trench capacitor may be located in a singulated chip.

Referring now to FIG. 3D which shows the stacked trench capacitor 100 after the stacking process. The second trench capacitor 102B may be formed in a similar manner as the first trench capacitor 102A as illustrated in FIGS. 3A-3D. In some embodiments, the stacking of the first trench capacitor 102A and second trench capacitor 102B may be achieved via the stacking and bonding of two wafers. For example, the wafer comprising the second trench capacitor 102B is first inverted such that the dielectric layer 107B is at the bottom while the substrate 101 is at the top, and then aligned over the other wafer comprising the first trench capacitor 102A. A suitable wafer bonding process is then performed to stack and bond the two wafers together such that the dielectric layers 107A and 107B are connected, the conductive layer 115 is connected to conductive layer 125, the insulator layer 117 is connected to the insulator layer 127, and the conductive layer 119 is connected to conductive layer 129. Subsequently, the substrate 101 of the top (inverted) wafer may be removed by a suitable material removal process, up to the insulating layer 103B. An oxide layer 111, for example, silicon dioxide may then be deposited over the insulating layer 103B. In other embodiments, the stacking of the first trench capacitor 102A and second trench capacitor 102B may be achieved via the stacking of a singulated chip on a wafer.

To form the contact structures such as the conductive plug 130, the via contact 131v1 and the via contact 131v2, respective openings are formed through the oxide layer 111, the insulating layer 103B, the active layer 105B and the dielectric layer 107B. A suitable material removal process including the use of a patterned mask may be applied. As an example, a layer of photoresist may be deposited over the oxide layer 111 and patterned to form a suitable patterned mask. To form the opening for via contact 131v1, an anisotropic material removal process, such as an anisotropic reactive ion etching (RIE) process, or a deep reactive ion etching (DRIE) process may be used to remove portions of the material stack below which are not covered by the patterned mask, forming openings extending from the oxide layer 111 to the top surfaces of conductive layer 125. To form the opening for the conductive plug 130 and via contact 131v1, a similar anisotropic etch process may be used to remove portions of the material stack below which are not covered by the patterned mask, except that the opening would need to extend from the oxide layer 111 to the top surface of conductive layer 129. In an embodiment, the opening for via contact 131v1 may be formed in a separate step from the opening for via contact 131v2 and conductive plug 130. An insulating material 123 may be deposited into the openings to line the sidewalls of the openings before depositing a layer of suitable conductive material, for example, copper, aluminum, tungsten, or any other suitable conductive material to fill up the openings to at least the top surface of the oxide layer 111, in order to form the conductive plug 130, via contact 131v1 and via contact 131v2. The excess conductive material, for example, over the top surface of the insulating layer may subsequently be removed by a suitable material removal process, for example, chemical mechanical planarization or etching process. The photoresist pattern for forming the openings may subsequently be removed. In embodiments with the silicided regions 106 connected by the additional vias 127v1 and 127v2, the vias 127v1 and 127v2 may be formed in a similar manner as via contacts 131v1 and 131v2 as aforementioned.

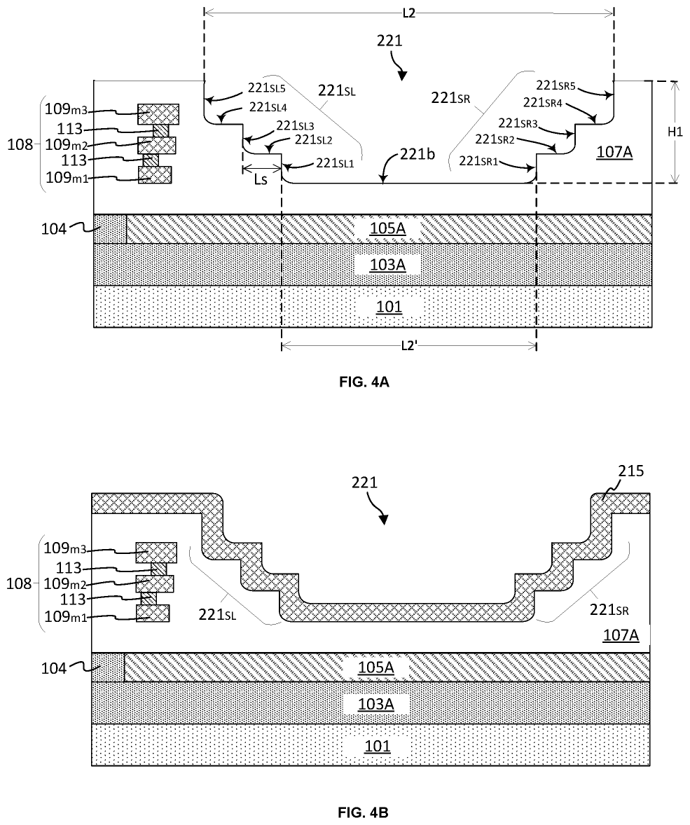

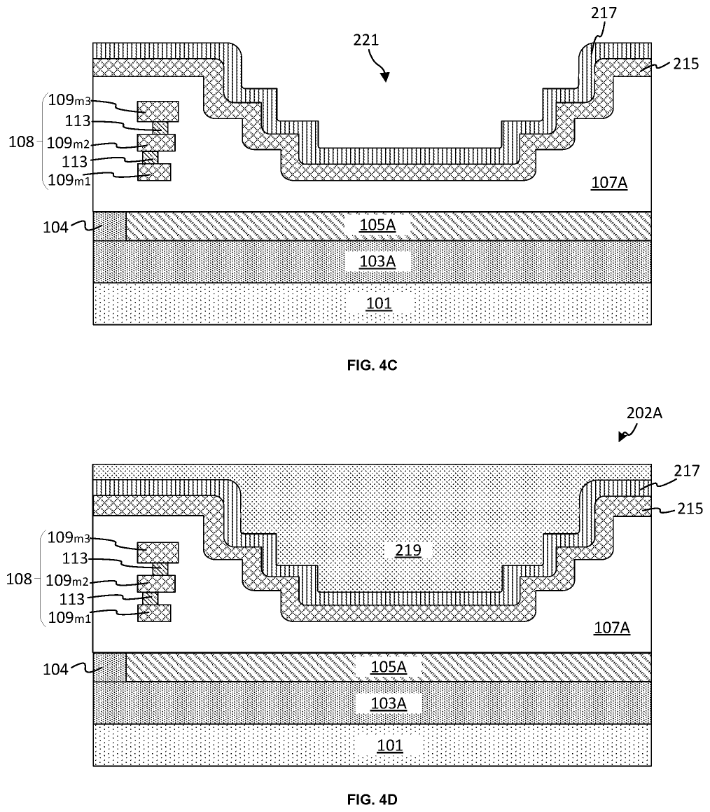

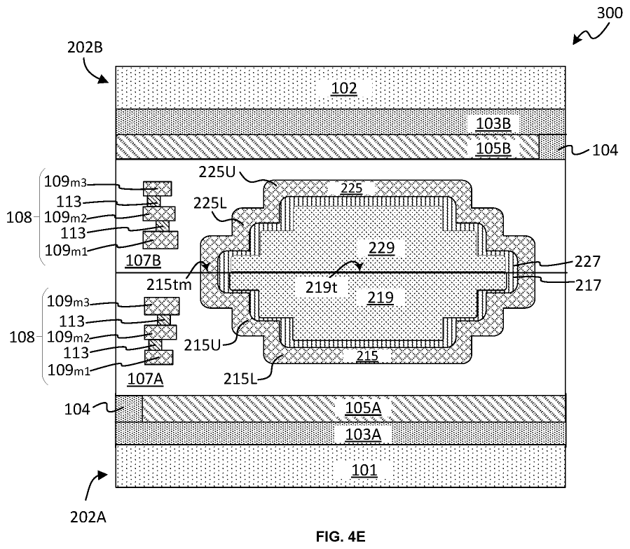

FIGS. 4A-4E illustrate another exemplary process flow for fabricating the stacked trench capacitor 200 according to some embodiments of the invention. In some embodiments, FIG. 4A may continue after the first material removal process in FIG. 3A, performing further material removal process steps to widen the upper portions of the trench 121, for example, to obtain trench sidewalls 221_{SL} and 221_{SR} each having a stepped profile. As an example, after the formation of trench 121 in FIG. 3A, additional masks and material removal process steps may be used to remove portions of dielectric layer 107A laterally adjacent to the trench 121, so as to obtain sub-surface 221_{SR2} and the adjoining sub-surface 221_{SR3}, as well as sub-surface 221_{SL2} and the adjoining sub-surface 221_{SL3}. The process may be repeated to further widen the upper portion of trench 121, forming sub-surface 221_{SR4} and the adjoining sub-surface 221_{SR5}, as well as sub-surface 221_{SL4} and the adjoining sub-surface 221_{SL5}, eventually forming trench 221 having stepped trench sidewalls 221L and 221_{SR} adjoining a bottom trench surface 221b. In some embodiments, the first material removal process may be designed to stop within the depth of the first metal (M1) level of the interconnect layer in the semiconductor device, for example, at the depth of the first metal line 109m1 at the first metal (M1) level within the interconnect layer. In other embodiments, the first material removal process may be designed to stop at a metal level above the first metal (M1) level, for example, at the second metal (M2) level. In some embodiments, the second material removal process used for forming sub-surface 221_{SR2} and the adjoining sub-surface 221_{SR3}, and sub-surface 221_{SL2} and the adjoining sub-surface 221_{SL3} may be designed to stop within the second metal (M2) level of the interconnect layer in the semiconductor device, for example, at the depth of the metal line 109m2 at the second metal (M2) level within the interconnect layer. For example, the sub-surfaces 221_{SR2} and 221_{SL2} may be at or within the second metal (M2) level. In a similar manner, additional material removal processes may be designed to stop within a metal level of the interconnect layer. In some embodiments, this may improve process efficiency by forming the openings for the interconnect structures 108 during the same process steps used for forming the stepped trench sidewalls. In other embodiments, the interconnect structure 108 may be formed at an earlier process step before the trench 221 is formed.

Still referring to FIG. 4A, the trench 221 may have a depth of H1, a lower width of L2′ which is measured from opposing sub-surfaces nearest to each other, and an upper width L2 which is measured from opposing sub-surfaces furthest from each other. For example, lower width L2′ may be measured from the closest opposing sub-surfaces 221_{SR1} and 221_{SL1}, and upper width L2 may be measured from the furthest opposing sub-surfaces 221_{SR5} and 221_{SL5}. The upper width L2 may be wider than the lower width L2′. A step may have a step width Ls, for example, the first step formed by sub-surfaces 221_{SL1} and 221_{SL2} may have a step width of Ls, measured from sub-surface 221_{SL1} to sub-surface 221_{SL3}. In some embodiments, the step width may be about a quarter of the lower width, for example, Ls may be equal to about ¼ L2′. In some embodiments, the width L2′ may be less than 2 microns (μm) and the depth H1 of the trench may be about 10 microns (μm).

Next referring to FIG. 4B, a conductive layer 215 is conformally deposited over the dielectric layer 107A and within the trench 221, the conductive layer 115 lining the stepped trench sidewalls 221_{SL} and 221_{SR}, and the bottom trench surface 221b in a continuous layer. A suitable deposition method may be plasma-enhanced chemical vapor deposition (PECVD) as an example. The process of forming the conductive layer 215 may include first depositing a liner layer over the trench sidewalls 221_{SL} and 221_{SR}, and the bottom trench surface 221b, followed by the deposition of a metallic layer over the liner layer. In some embodiments, the thickness of the liner layer may be in the range of 10 to 20 nanometers (nm), while the thickness of the conductive layer 115 may be in the range of 100 to 500 nanometers (nm).

Next, referring to FIG. 4C, an insulator layer 217 is deposited over the conductive layer 215 with a suitable process, such as low-pressure chemical vapor deposition (LPCVD), plasma-enhanced chemical vapor deposition (PECVD) as examples. In some embodiments, the thickness of the insulator layer 217 may be in the range of 50 to 500 nanometers (nm).

Now referring to FIG. 4D, another conductive layer 219 is deposited over the insulator layer 217 and within the trench 221. Conductive layer 219 may fill up the remaining space within the trench 221 and over the topmost surface of the dielectric layer 107A. A suitable deposition method may be plasma-enhanced chemical vapor deposition (PECVD) as an example. Subsequently, to obtain a planar or substantially planar top surface where the top surfaces of dielectric layer 107A, conductive layer 215, and conductive layer 219 are coplanar or substantially coplanar, a suitable material removal process may be performed prior to the stacking of the trench capacitors as shown in FIG. 4E. A suitable material removal process may be, for example, chemical mechanical planarization or an etching process to remove the excess material from the top surface of the device. After the material removal process, the top surface 219t of the conductive layer 219 is coplanar with the topmost surface 215tm of the conductive layer 215 and the top surface of the dielectric layer 107A. The first trench capacitor 202A is now completed, having a coplanar top surface suitable for the subsequent stacking process. In some embodiments, the first trench capacitor 202A may be arranged in an array within a wafer, comprising similar trench capacitors. In other embodiments, the first trench capacitor may be located in a singulated chip.

Referring now to FIG. 4E which shows the stacked trench capacitor 300 after the stacking process. The second trench capacitor 202B may be formed in a similar manner as the first trench capacitor 202A as illustrated in FIGS. 4A-4D and the corresponding descriptions. In some embodiments, the stacking of the first trench capacitor 202A and second trench capacitor 202B may be achieved via the stacking of two wafers. For example, the wafer comprising the second trench capacitor 202B is first inverted such that the dielectric layer 107B is at the bottom while the substrate 101 is at the top, and then aligned over the other wafer comprising the first trench capacitor 202A. A suitable wafer bonding process is then performed to stack and join the two wafers together such that the dielectric layers 107A and 107B are connected, the conductive layer 215 is connected to conductive layer 225, the insulator layer 217 is connected to the insulator layer 227, and the conductive layer 219 is connected to conductive layer 229. Subsequently, the substrate 101 of the top (inverted) wafer may be removed by a suitable material removal process, up to the insulating layer 103B. An oxide layer 111, for example, silicon dioxide may then be deposited over the insulating layer 103B. In other embodiments, the stacking of the first trench capacitor 202A and second trench capacitor 202B may be achieved via the stacking of a singulated chip onto a wafer.

To form the stacked trench capacitor 300 having the associated contact structures as shown in FIG. 2, processes as described for forming the contact structures of stacked trench capacitor 100 may be similarly employed and need not be repeated here.

Descriptions of embodiments herein are meant to be taken as examples and not meant to be limiting as such. Terms such as “vertical”, “horizontal”, “top”, “bottom”, “over”, “under”, and the like in the description and in the claims, if any, are used for establishing a frame of reference and not necessarily for describing permanent relative positions. The term “horizontal” is defined as a plane parallel to a conventional plane of a semiconductor substrate, rather than its actual three-dimensional orientation in space. The terms “vertical” and “normal” refer to a plane perpendicular to the horizontal. The term “lateral” refers to a direction parallel to the horizontal plane.

Terms such as “connected” or “coupled” indicate that a feature may be directly connected or coupled to or with the other feature, or one or more intervening features may also be present. A feature may be “directly connected” or “directly coupled” to or with another feature if intervening features are absent. A feature may be “indirectly connected” or “indirectly coupled” to or with another feature if at least one intervening feature is present. Terms such as “on” or “contacting” indicate that a feature may be directly on or in direct contact with the other feature, or one or more intervening features may also be present. A feature may be “directly on” or in “direct contact” with another feature if intervening features are absent. A feature may be “indirectly on” or in “indirect contact” with another feature if at least one intervening feature is present.

The terms “first”, “second”, “third” and the like in the description and in the claims, if any, are used for distinguishing between similar elements and not necessarily for describing a particular sequential or chronological order as required. A method described herein is not necessarily limited in practice to the exact order or number of steps as have been listed, and certain steps may possibly be omitted and/or certain other steps not described herein may possibly be performed in actual practice. Terms such as “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in one embodiment” herein do not necessarily all refer to the same embodiment.

While several exemplary embodiments have been presented in the above detailed description of the device, it should be appreciated that a number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

What is claimed is:

1. A semiconductor device comprising:
a dielectric layer over a semiconductor substrate;
a first conductive layer in the dielectric layer;
a capacitor dielectric layer in the dielectric layer; and
a second conductive layer in the dielectric layer, wherein the second conductive layer encircles the capacitor dielectric layer and the first conductive layer.

2. The semiconductor device of claim 1, wherein the second conductive layer has a width that is wider than a width of the first conductive layer.

3. The semiconductor device of claim 1, further comprising a first via contact above and connected to the first conductive layer.

4. The semiconductor device of claim 3, further comprising a second via contact above and connected to the second conductive layer, wherein the second via contact laterally overlaps with the first conductive layer.

5. The semiconductor device of claim 3, wherein the first via contact is electrically isolated from the second conductive layer.

6. The semiconductor device of claim 1, further comprising an insulating layer above the semiconductor substrate.

7. The semiconductor device of claim 1, further comprising an active layer above the first conductive layer.

8. The semiconductor device of claim 7, further comprising another active layer below the first conductive layer.

9. The semiconductor device of claim 1, wherein the second conductive layer has an upper portion at a first metal (M1) level in the semiconductor device.

10. The semiconductor device of claim 1, wherein the second conductive layer has a lower portion at or above a first metal (M1) level in the semiconductor device.

11. The semiconductor device of claim 1, wherein the first conductive layer has sidewalls having a stepped profile.

12. The semiconductor device of claim 1, wherein the second conductive layer has sidewalls having a stepped profile.

13. A semiconductor device comprising:
a first semiconductor substrate having a first active layer;
a first dielectric layer over the first semiconductor substrate;
a first conductive layer and a second conductive layer in the first dielectric layer, the second conductive layer is above the first conductive layer;
a first insulator layer over the first conductive layer, wherein the first insulator layer spaces the first conductive layer from the second conductive layer;
a third conductive layer and a fourth conductive layer in a second dielectric layer, the third conductive layer directly contacting the second conductive layer and the fourth conductive layer is above the third conductive layer, wherein the third conductive layer has sidewalls adjoining a top surface;
a second insulator layer over and conformal to the sidewalls and the top surface of the third conductive layer, wherein the second insulator layer spaces the third conductive layer from the fourth conductive layer; and
a second semiconductor substrate over the fourth conductive layer, the second semiconductor substrate having a second active layer.

14. The semiconductor device of claim 13, wherein the fourth conductive layer has an upper portion between lower portions, wherein the upper portion is substantially horizontal and has a topmost surface.

15. The semiconductor device of claim 14, wherein the first conductive layer has a lower portion arranged within a first metal level in a first interconnect layer, and the upper portion of the fourth conductive layer is arranged within a second metal level in a second interconnect layer, wherein the first metal level in the first interconnect layer is the same as the second metal level in the second interconnect layer.

16. The semiconductor device of claim 13, wherein the fourth conductive layer is connected to the first conductive layer.

17. The semiconductor device of claim 13, wherein the first insulator layer is connected to the second insulator layer.

18. The semiconductor device of claim 13, wherein the first conductive layer has a top surface that is coplanar with a top surface of the second conductive layer.

19. A method of fabricating a semiconductor device comprising:
forming a first trench capacitor, including forming a first conductive layer, a first insulator layer and a second conductive layer in a first dielectric layer, wherein the second conductive layer is above the first conductive layer and the first insulator layer spaces the first conductive layer from the second conductive layer;
forming a second trench capacitor, including forming a third conductive layer, a second insulator layer and a fourth conductive layer in a second dielectric layer, wherein the third conductive layer is above the fourth conductive layer and the second insulator layer spaces the third conductive layer from the fourth conductive layer;
inverting and aligning the second trench capacitor over the first trench capacitor such that the first conductive layer is contacting the fourth conductive layer and the second conductive layer is contacting the third conductive layer; and
connecting the first conductive layer to the fourth conductive layer and the second conductive layer to the third conductive layer.

20. A method according to claim 19, wherein the forming of the first trench capacitor includes forming a trench with trench sidewalls each having a stepped profile.
